(19) United States
(12) Patent Application Publication
(10) Pub. No.: US 2008/0264776 A1
(43) Pub. Date: Oct. 30, 2008

(54) Methods of Making Gold Nitride

(76) Inventors: Lidija Siller, Whitley Bay (GB); Satheesh Krishnamurthy, Dublin (IE); Yimin Chao, Newcastle Upon Tyne (GB)

Correspondence Address: BUCHANAN, INGERSOLL & ROONEY PC, POST OFFICE BOX 1404, ALEXANDRIA, VA, 22313-1404, US

(21) Appl. No.: 11/628,870

(22) PCT Filed: Jun. 3, 2005
(86) PCT No.: PCT/GB2005/002197

§ 371 Date: Dec. 8, 2006

(30) Foreign Application Priority Data
Jun. 10, 2004 (GB) 0413036.5

(51) Int. Cl. C23C 14/00

(52) U.S. Cl. 204/192.17

(57) ABSTRACT

A method of treating a gold film to form gold nitride is proposed, which includes the steps of: generating a nitrogen plasma with a radio frequency field and a power of less than or equal to about 2 kW; and treating said gold film with said nitrogen plasma. The method can be carried out using commercially available apparatus such as an etching machine. The radio frequency field is preferably between 10 and 17 MHz, and the power used to generate the nitrogen plasma is preferably less than or equal to 300 W. The gold film may be biased to achieve directional attack of the plasma. A further method of forming gold nitride is proposed which includes the step of sputtering from a gold target with a nitrogen plasma to form a film of gold nitride on a substrate.

This invention relates to methods of making gold nitride.

Gold is widely used in a number of industries including electronics, instrumentation in the biological sciences, as an essential part of medical diagnostic devices, etc. It is an expensive commodity and limited as an earth resource. In industrial applications, gold is often applied as a thin film applied to less expensive substrates, however often there is a limitation as to the minimum thickness of such a film as gold is a soft metal and easily abraded. Various methods have been found for increasing the gold film's hardness by alloying it with other metals, and whilst these methods suffice, the gold still represents a significant expense to industry. The current invention relates to methods of forming gold nitride in particular as part of a gold film which preferably seek to significantly increase the hardness of the gold film and so allow much thinner layers of gold to be used, thereby potentially yielding significant economic benefits to industry.

The physical properties of electroplated gold films are known to be influenced by incorporated impurities or inclusions, as well as by extraneous materials on the surface of the gold film. In electrodepositing methods, a granular structure is known to occur and is believed to be a reason for the rapid wear of electrodeposited gold films. It is thought that gold nitride will be a harder wearing surface, with many potential applications.

The only successful attempt at forming gold nitride in the literature is a paper co-authored by one of the present inventors (\check{S}iller, L., et al., Surf. Sci., 513, 78-82 (2002)), which used nitrogen ion irradiation under ultra-high vacuum conditions. The presence of gold nitride as a result of this method was demonstrated by the use of high resolution X-ray photoemission spectroscopy to determine N1s core level spectra. However, the process described in this paper is unsuitable for scaling to industrially useful levels of production as it requires an ultra-high vacuum which is difficult and costly to achieve.

The present inventors have developed new methods for the formation of gold nitride. The first of these methods involves the treatment of a gold thin film with a nitrogen plasma that has been generated by a radio frequency field (“a nitrogen radio frequency plasma”) and which has been generated with a power less than or equal to about 2 kW.

The radio frequencies to generate the plasma may be above 10 kHz, but are preferably between 1 MHz and 1 GHz, more preferably between 5 MHz and 20 MHz, with frequencies between 10 and 17 MHz being most preferred. A particularly preferred radio frequency for generating the nitrogen plasma is 13.56 MHz.

This method avoids the need for an ultra-high vacuum, and can be carried out using commercially available apparatus.

Accordingly, a first aspect of the present invention provides a method of treating a gold film to produce gold nitride, comprising the step of subjecting a gold film to a radio-frequency nitrogen plasma generated with a power of less than or equal to about 2 kW.

Preferably the gold film is a thin film, i.e. a film having a thickness of up to 10 microns, although a thickness of 2 microns or less is more preferred. Preferably the film is supported on an appropriate substrate. The thickness of the film of gold nitride produced by this method is likely to be somewhat less than the thickness of the original film, due to removal of surface layers by plasma etching. The gold film may in particular be deposited on a substrate, for example a silicon wafer, by using a standard sputter coating system.

Accordingly, a second aspect of the present invention provides a method of making a film of gold nitride, comprising the steps of:

a) sputter coating a substrate to form a gold film; and
b) subjecting the gold film to a radio-frequency nitrogen plasma generated with a power of less than or equal to about 2 kW.

Using a greater power to generate the radio-frequency nitrogen plasma would destroy the gold nitride surface as it is formed. The power used to generate the radio-frequency nitrogen plasma is preferably less than or equal to about 1 kW, more preferably 500 W and is most preferably less than or equal to 300 W and may be possibly less than or equal to about 100 W. It has been found that a plasma generated with a power of about 300 W produces the most gold nitride per cycle of plasma treatment, due to a more favourable ratio between N⁺ (and/or N⁺⁺) and N₂⁺ ions in the plasma, N⁺/N⁺⁺ being preferred to N₂⁺ ions.

It is preferred that the gold film is biased so as to achieve directional attack of the nitrogen plasma. The voltage used to bias the sample is preferably less than or equal to 1000 V, more preferably less than 700 V, and is most preferably less than or equal to 500 V. It is thought that a lower biasing voltage prevents removal of the gold nitride being formed by excessive plasma etching. One convenient device which can be used to carry out the method of the invention is an etching machine. These are usually employed to produce high powered plasma, but can be adapted to generate the plasmas required by the present invention and also have the facility to bias the sample plate.

The second method involves sputtering from a gold target with a nitrogen plasma, and the deposition of a film on a substrate. The film may contain gold and gold nitride.

Using this method, any thickness of film can be generated. As with the first method above, this second method avoids the need for an ultra-high vacuum, and thus can be carried out using commercially available apparatus.

Accordingly, a third aspect of the present invention provides a method of making gold nitride, comprising the step of sputtering from a gold target with a nitrogen plasma to form a film on a substrate.

In embodiments of the invention, the substrate is a Si wafer, but other substrates can be used.

The plasma of this method may be generated by any known method (e.g. RF, AC, DC, DC pulsed etc.). In preferred embodiments of the invention, an RF plasma is used.

The power used to generate the nitrogen plasma is preferably less than or equal to about 1 kW, more preferably 500 W and is most preferably less than or equal to 300 W and may be possibly less than or equal to about 100 W. It has been found that a plasma generated with a power of about 300 W produces the most gold nitride per cycle of plasma treatment, due to a more favourable ratio between N⁺ (and or N⁺⁺) and N₂⁺ ions in the plasma, N⁺/N⁺⁺ being preferred to N₂⁺ ions.

It is preferred that the gold target is biased so as to achieve directional attack of the nitrogen plasma. The voltage used to bias the target is preferably less than or equal to 1000 V, more preferably less than 700 V, and is most preferably less than or equal to 500 V.

The partial pressure of nitrogen used for sputtering is preferably between 1×10⁻³ and 1×10⁻² mbar, and more preferably between about 3×10⁻³ and about 5×10⁻³ mbar.

One stoichiometry of the gold nitride produced by the present methods is Au₃N.

A further aspect of the present invention provides gold nitride obtainable by or obtained by the methods of the previous aspects, including any combination of the preferred or optional features of those aspects.

Embodiments of the present invention will now be described by way of example, and with reference to the following figures, in which:

FIG. 1 shows the photoemission spectrum of the gold nitride film of Example 1;

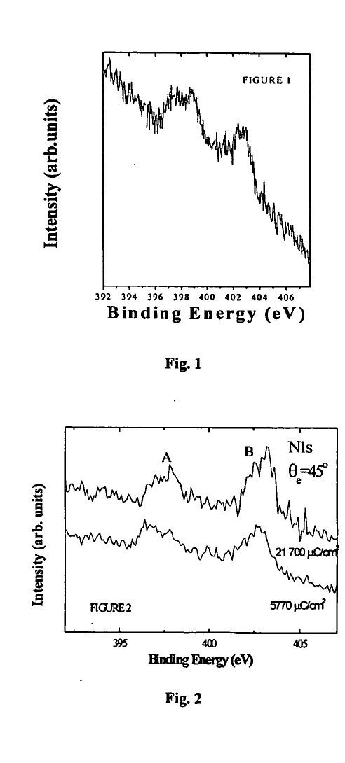

FIG. 2 shows photoemission spectra of gold nitride films synthesised by the ion implantation method of the prior art (\check{S}iller, L., et al., Surf. Sci., 513, 78-82 (2002));

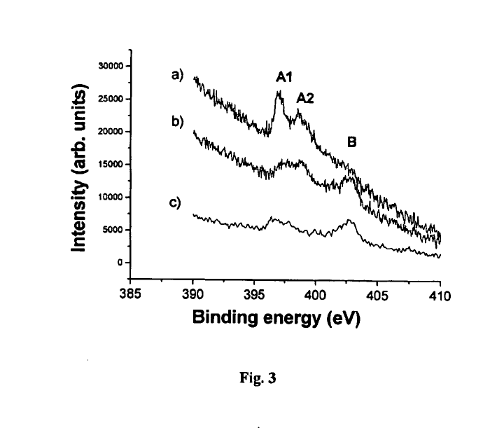

FIG. 3 shows the photoemission spectra of gold nitride films produced by three different methods;

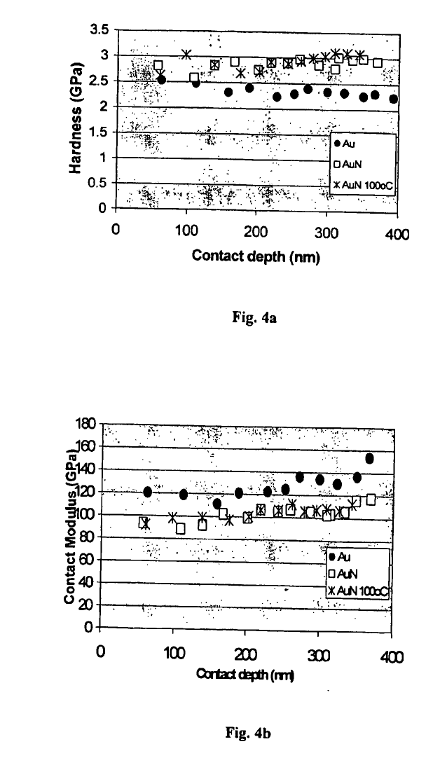

FIGS. 4a and 4b show respectively the variation of hardness and contact modulus with contact depth for gold, gold nitride and heated gold nitride at 100° C.;

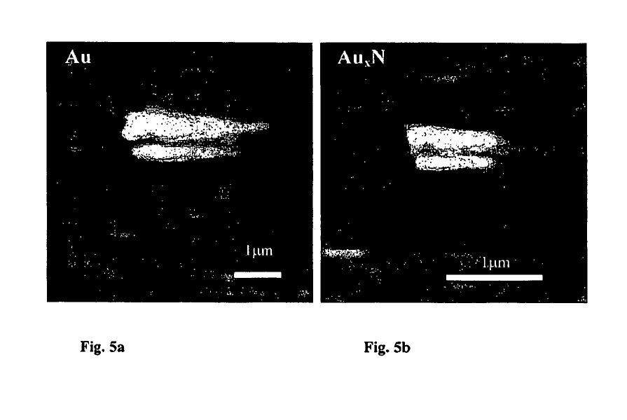

FIGS. 5a and 5b show atomic force microscopy images of an indent in respectively gold and gold nitride; and

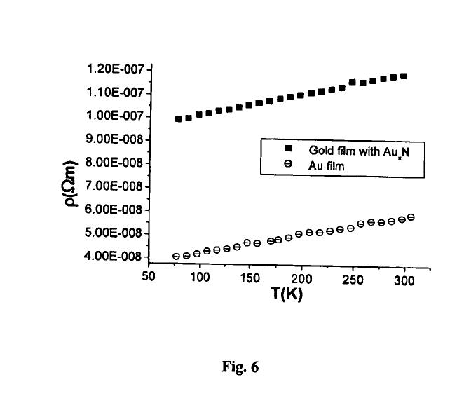

FIG. 6 shows the resistivity as a function of temperature for a gold film containing gold nitride and an unaltered gold film.

### EXAMPLE 1

A gold film 1 to 2 microns thick was deposited on a standard 100 mm wafer using a sputter coating system (Science technology systems (STS), machine type: BOC Edwards Sputter system). The gold nitride was then formed by exposing the gold film to plasma generated by a radio frequency field. The power employed to generate plasma was 300 W and the target was biased to −240 V. The nitrogen pressure in the plasma chamber was 6.4 mTorr, and the flow rate of N₂ was 50 sccm (cubic centimeter per second). The plasma was generated by radio frequency at 13.56 MHz and the growth time was about thirty minutes, which is the length of the plasma treatment. The manual automatic pressure controller (APC) angle of the system was set to 91°.

The photoemission spectrum of the material produced is presented in FIG. 1, taken at the National Centre for Electron Spectroscopy and Surface Analysis (NCESS), Daresbury Laboratory, Warrington, United Kingdom with a monochromatic X-ray source and an ESCA 300 analyser, which was used for all the spectra presented herein.

Photoemission spectra of the N1s core level spectra obtained from an Au(110) surface exposed to a nitrogen ion dose of 5770 μC/cm² and 21 700 μC/cm² at 500 eV and at room temperature, according to the method described in \check{S}iller, L., et al., Surf. Sci., 513, 78-82 (2002) are shown in FIG. 2. Peaks A in these spectra are attributed to the gold-nitride and peaks B to nitrogen bubble formation in gold. The shape and the position of the peaks in both FIGS. 1 and 2 are almost identical, leading to the conclusion that the plasma treatment of the present invention also results in the formation of gold nitride.

### EXAMPLE 2

The method of Example 1 was repeated, but generating the radio-frequency plasma using a power of 100 W, and biasing the target at between −200 and −310 V.

### EXAMPLE 3

A 2 μm thick gold film containing gold nitride was produced on a silicon wafer using an Edwards AUTO 500 Magnetron sputtering system with a gold target and a nitrogen plasma.

The system was operated at a typical power of 300 W, and the target bias voltage was 490V. The partial pressure of nitrogen in the sputtering system was held constant at 5×10⁻³ mbar, yielding a deposition rate of approximately 0.2 nm/s.

The photoemission spectrum of the material produced is presented as spectrum a) in FIG. 3, using the ESCA 300 analyser as for Example 1 above. The other spectra are: b) a thin film of gold nitride produced by the method of Example 1, and c) a Au(110) surface exposed to a nitrogen dose of 577 μC/cm² at 500 eV impact ion energy (as also shown in FIG. 2).

The shape and the position of all the peaks in FIG. 3 are almost identical to each other, leading to the conclusion that the sputtering method of the present invention also results in the formation of gold nitride.

The percentage of gold nitride in the film of this Example is ˜10.5%, which has been determined from the area ratio of gold Au_{4f} and nitrogen N1s photoemission peaks, corrected for the photoionisation cross sections (according to the method set out in J. J. Yeh, Atomic Calculations of Photoionization Cross-Sections and Asymmetry Parameters, Gordon and Breach Science Publishers, 1993), and the transmission of the ESCA 300 analyser with the proposed triclinic stoichiometry of Au₃N.

Below we set out measurements of the electrical conductivity and hardness of a gold nitride film prepared in accordance with Example 3 and compare them with conductivity and hardness of pure gold films of the same thickness prepared by sputter deposition using an argon plasma.

The mechanical measurements were made with a Hysitron Triboindenter fitted with a sharp diamond tip of cube corner geometry (˜40 nm tip end radius), carefully calibrated using a fused silica standard according to the method of Oliver and Pharr (see W. C. Oliver and G. M. Pharr, J. Mater. Res., 7, 1564 (1992)). Twenty five indentations were made on each sample in a five by five array with a separation of five microns between each indent. Tests were performed at peak loads from 100 to 2500 μN under load control.

Hardness and contact modulus, Er, were initially determined from the load displacement curves produced using the method of Oliver and Pharr. Accordingly, the contact modulus is given by:

$$\frac{1}{{E}_{r}} = \frac{1 - {v}_{1}^{2}}{{E}_{1}} + \frac{1 - {v}_{2}^{2}}{{E}_{2}} \qquad ( 1 )$$

where E and ν are the Young's Modulus and Poisson's ratio respectively and the subscripts 1 and 2 refer to indenter and sample respectively. Although the elastic constants of the diamond indenter are well known it is not possible to determine the Young's Modulus of an unknown sample exactly unless the Poisson's ratio is known. For this reason the coatings tested in this study are characterised in terms of the contact modulus alone.

The Oliver and Pharr approach gives unreasonable results for these properties in gold due to the effects of pile-up around the indentation. The considerable pile-up of the films is visible in the AFM images of the indents shown in FIGS. 5a and 5b. The amount of pile-up is reduced for the gold nitride coating.

To correct for this pile-up, the indent area was determined at the end of the test by AFM scans using the tip which made the indent. For all coatings tested the hardness is approximately constant until the indenter penetration is greater than 25% of the coating thickness, at which point the substrate starts to have an effect on the measured data and the hardness rises. Similar observations have been made for other soft materials such as aluminium.

As shown in FIGS. 4a and 4b, the uncorrected hardness of the gold is lower than that of the gold nitride whereas its uncorrected contact modulus is higher. Annealing of the gold nitride has little or no effect on its mechanical properties.

The average hardness and contact modulus of the films before and after correction are shown in Table 1.

TABLE 1
Hardness and contact modulus values for samples described above

| | As-measured | | Pile-up corrected | |
|---|---|---|---|---|
| | Contact | | Contact | |
| | Modulus | Hardness | modulus | Hardness |
| Sample | (GPa) | (GPa) | (GPa) | (GPa) |
| Sputter | 128 ± 12 | 2.35 ± 0.09 | 118 ± 11 | 2.01 ± 0.01 |
| deposited | | | | |
| gold | | | | |
| AuₓN | 103 ± 8 | 2.87 ± 0.11 | 106 ± 8 | 3.02 ± 0.12 |
| AuₓN (100° C. | 106 ± 10 | 2.92 ± 0.16 | 110 ± 10 | 3.17 ± 0.17 |
| anneal) | | | | |
| Bulk gold | | | 88 ± 8 | 0.64 ± 0.05 |
| Electroplated | | | 98 ± 10 | 1.29 ± 0.15 |
| gold | | | | |

Therefore, it can be seen that, within experimental error, the contact modulus of the sputter deposited gold and the gold nitride is the same but the hardness of the gold nitride is about 50% higher.

In comparison with gold electroplate and bulk gold the values for both hardness and contact modulus are higher. In both cases this is probably due to the small grain size of the coatings. For large grained material, where the indent samples a single grain, the measured contact modulus is usually close to the Hill or Voigt average for single crystal properties (see Table 2 below), as is observed for the bulk and electroplated gold coatings here.

TABLE 2
Calculated elastic properties of gold from single crystal parameters
(c₁₁ = 190 GPa, c₁₂ = 161 GPa and c₄₄ = 42.3 GPa [15])

| | Elastic | Poisson's | Contact |
|---|---|---|---|
| Property | Modulus (GPa) | ratio | Modulus (GPa) |
| Tensile | 68.8 | 0.433 | 89 |
| Hill average | 78.5 | 0.423 | 88.2 |
| Voigt average | 88.1 | 0.414 | 97.3 |

The hardness of the coating is critically dependent on its grain size, increasing as the grain size is reduced down to a certain limiting size, the so-called Hall-Petch behaviour. AFM measurements of the surfaces of the films tested here indicate that the grain size of the electroplated and bulk gold is much larger than the indentation size (see Table 3) but that the plasma deposited films have a much smaller grain size and the indentation will therefore sample several grains. The hardness of the gold scales as the reciprocal of the square root of the grain size as might be expected for Hall-Petch behaviour. In such circumstances film texture and the presence of grain boundaries can also have an effect on the measured contact modulus, particularly since elastic averaging methods are not reliable when only applied to material in a small number of grains.

TABLE 3
Apparent grain size of gold and gold nitride
layers from AFM scans of the sample surface

| | Coating thickness | |
|---|---|---|
| Material | (μm) | Grain size (μm) |
| Sputter deposited | 1.5 | 0.39 ± 0.12 |
| gold | | |
| AuₓN | 1.5 | 0.25 ± 0.13 |
| AuₓN 100° C. anneal | 1.5 | 0.28 ± 0.12 |
| Electroplated gold | 17 | 5.8 ± 0.7 |
| Gold Foil | 200 | 150 ± 15 |

FIG. 6 shows conductivity measurements made over a temperature range of 77 K to 298 K for a 2.12 μm thick gold film with ˜10.5% gold nitride produced via reactive ion sputtering. The conductivity of the film was measured in the Van der Pauw geometry, thus eliminating the contact resistance which may be greater than the sample itself. As a comparison the resistivity of a pure gold film ˜1.96 μm thick over the same temperature range is plotted. We find that the resistivity of the gold nitride film is 11.9·10⁻⁸ Ω·m at room temperature, whereas pure gold has a bulk resistivity of 2.2·10⁻⁸ Ω·m at room temperature. Together these results suggest that the gold nitride film is still a metallic conductor.

The above results demonstrate that gold films with incorporated gold nitride are harder than pure gold, but remain metallic and confirm that a gold nitride phase may be produced in large area films under conditions which may be readily scaled.

1. A method of treating a gold film to form gold nitride including the steps of: generating a nitrogen plasma with a radio frequency field and a power of less than or equal to about 2 kW; and
treating said gold film with said nitrogen plasma.

2. A method according to claim 1 wherein the radio frequency field used to generate said nitrogen plasma is between 1 MHz and 1 GHz.

3. A method according to claim 2 wherein the radio frequency field is between 10 and 17 MHz.

4. A method according to any claim 1 wherein the gold film has a thickness of less than 2 microns.

5. A method according to claim 1 wherein the power used to generate said nitrogen plasma is less than or equal to 500 W.

6. A method according to claim 5 wherein the power used to generate said nitrogen plasma is less than or equal to 300 W.

7. A method according to claim 1 further including the step of biasing the gold film.

8. A method according to claim 7 wherein the bias voltage is less than or equal to 1 kV.

9. A method according to claim 8 wherein the bias voltage is less than or equal to 500 V.

10. A method according to claim 1 which is carried out in an etching machine.

11. A method of making a film of gold nitride including the step of: treating a gold film using a method according to claim 1.

12. A method according to claim 11, further including the step of forming said gold film by sputter coating a substrate.

13. A method of making gold nitride, comprising the step of sputtering from a gold target with a nitrogen plasma to form a film on a substrate.

14. A method according to claim 12 wherein the substrate is silicon wafer.

15. A method according to claim 13 wherein the power used to generate said nitrogen plasma is less than or equal to 500 W.

16. A method according to claim 15 wherein the power used to generate said nitrogen plasma is less than or equal to 300 W.

17. A method according to claim 13 further including the step of biasing the gold target.

18. A method according to claim 17 wherein the bias voltage is less than or equal to 1 kV.

19. A method according to claim 18 wherein the bias voltage is less than or equal to 500 V.

20. Gold nitride obtainable by the method of claim 1.

21. Gold nitride obtainable by the method of claim 13.
